(19) United States
(12) Patent Application Publication
(10) Pub. No.: US 2007/0096644 A1
(43) Pub. Date: May 3, 2007

(54) Organic electroluminescent element and organic electroluminescent display device

(75) Inventors: Kazuki Nishimura, Mie (JP); Yuji Hamada, Nara (JP); Masaya Nakai, Osaka (JP)

Correspondence Address: MASUVALLEY & PARTNERS, 8765 AERO DRIVE, SUITE 312, SAN DIEGO, CA, 92123, US

(73) Assignee: SANYO Electric Co., Ltd.

(21) Appl. No.: 11/585,592

(22) Filed: Oct. 24, 2006

(30) Foreign Application Priority Data
Oct. 28, 2005 (JP) JP2005-314791

(51) Int. Cl. H01L 51/54

(52) U.S. Cl. 313/506; 428/690; 428/917; 428/212; 313/504; 257/E51.05

(57) ABSTRACT

An organic electroluminescent element and display device is provided with anode, cathode, a light emitting layer arranged between the anode and cathode, and at least 3 organic layers arranged between the light emitting layer and the anode. The organic electroluminescent element is characterized by an absolute value |LUMO(A)| of an energy level of a Lowest Unoccupied Molecular Orbital (LUMO) for the first organic layer provided to the anode side of the organic layers and an absolute value |LUMO(B)| of an energy level of a the LUMO for the second organic layer adjacent to the cathode side of the first organic layer having a relationship of |LUMO(A)|<|LUMO(B)|.

### TECHNICAL FIELD

The present invention relates to an organic electroluminescent element and an organic electroluminescent display device.

### BACKGROUND OF INVENTION

Organic electroluminescent elements (organic EL elements) have been actively developed in the light of display or illumination applications. The drive principles of an organic EL element are as follows. That is, hole and electron injected from anode and cathode respectively, transported within an organic thin film, recombine in a light emitting layer which leads to an excitation condition and light emission is obtained from the excitation condition. To increase luminescence efficiency, it is necessary to effectively inject hole and electron and to transport within an organic thin film.

Generally, a charge transport layer and a charge injection layer are provided between electrode and a light emitting layer to transport hole or electron.

As a prior art for such a technical field, it is suggested in Japanese Published Unexamined Patent Publication No. 2003-151776 to lower conduction band lowest level of base material for an electron capture layer than conduction band lowest level of base material for a hole transport layer and a light emitting layer in the structure with hole injection layer, hole transport layer, electron capture layer, light emitting layer, and electron transport layer laminated from anode to cathode. This prevents deterioration of base material of a hole transport layer on anode side.

In Japanese Published Unexamined Patent Publication No. 2004-207000, it is suggested that a mixed layer comprised by constituent material of adjacent hole transport layers to be mediated on the interface of two adjacent layers of hole transport layer, thereby improving adhesion of two adjacent layers of charge transport layer which enables an improvement of luminous efficiency and luminance life.

In Japanese Published Unexamined Patent No. 2003-229269, it is suggested that alternately laminate a cathode buffer layer and an electron transport layer at least twice between a cathode and a light emitting layer to control electron transport efficiency.

Also, SYNTHESIS, April, 1994, page 378-380 “Improved Synthesis of 1,4,5,8,9,12-Hexaazatriphenylenehexacarboxylic Acid” is another public known reference.

Third arylamine series material such as NPB (N,N′-di(naphthacene-1-yl)-N,N′-diphenylbenzdine) have been used for hole transport layers, however, there is a problem of drive voltage being high due to low carrier mobility of hole transport property material, such as NPB, when the thickness of film for the hole transport layer which is comprised of NPB is increased to adjust cavity. Thus, there has been a demand for an element structure of an organic EL element that can reduce drive voltage even when film thickness of NPBs are increased.

The objective of this invention is to provide an organic electroluminescent element and an organic electroluminescent display devise with high luminous efficiency which can reduce drive voltage.

### BRIEF SUMMARY OF THE INVENTION

The organic EL element according the present invention having anode, cathode, a light emitting layer arranged between the anode and cathode, at least 3 organic layers arranged between the light emitting layer and the anode, is characterized by an absolute value |LUMO(A)| of energy level of a Lowest Unoccupied Molecular Orbital (LUMO) for the first organic layer provided to the anode side of organic layers and an absolute value |LUMO(B)| of energy level of a Lowest Unoccupied Molecular Orbital (LUMO) for the second organic layer provided adjacent to the cathode side of the first organic layer having a relationship of |LUMO(A)|<|LUMO(B)|, and an absolute value |HOMO(C)-LUMO(B)| for the difference between an energy level HOMO(C) of a Highest Occupied Molecular Orbital (HOMO) for the third organic layer provided adjacent to the cathode side of the second organic layer and LUMO(B) of the second organic layer having a relationship of |HOMO(C)-LUMO(B)|≦1.5 eV.

In the present invention, the first organic layer, second organic layer and third organic layer are arranged between light emitting layer and anode, and LUMO(A) of the first organic layer and LUMO (B) of the second organic layer are in a relation ship of |LUMO(A)|<|LUMO(B)|. . . (1).

Also, LUMO (B) of the second organic layer and HOMO(C) of the third organic layer are in a relationship of |HOMO(C)-LUMO(B)|≦1.5 eV . . . (2).

In the present invention, difference of HOMO (C) of the third organic layer and LUMO(B) of the second organic layer is 1.5 eV or below since the equation (2) above is satisfied. For this reason, the second organic layer can easily pull electron out of the third organic layer.

Also, since the equation (1) above is satisfied, the electrons pulled out of the third organic layer by the second organic layer are blocked by the first organic layer and accumulated in the second organic layer. For this reason, a higher electrical field is applied locally. It is considered that by following the present invention, such high electrical field is applied changing the energy band so that a decrease of drive voltage can be attained.

In the present invention, an absolute value |HOMO(A)| of energy level of a Highest Occupied Molecular Orbital (HOMO) for the first organic layer and an absolute value |HOMO(B)| of energy level of a Highest Occupied Molecular Orbital (HOMO) for the second organic layer are desirable to be in a relationship of |HOMO(A)|<|HOMO(B)| . . . (3)

By satisfying the equation (3) above, holes are accumulated on the interface of the first organic layer and the second organic layer, since the holes trying to flow from the first organic layer to the second organic layer are blocked by an energy barrier of the second organic layer. It is thought that this enables to further apply a higher electrical field locally, thereby further decreasing drive voltage.

In the present invention, the first organic layer and the third organic layer are desirable to be formed from a hole transport property material. Such a hole transport property material, for example, can be third arylamine series material.

In the present invention, materials which satisfy equations (1) and (2) above are used for the second organic layer. The second organic layer in the present invention, acts as an electron pull-out layer which pulls electrons out of the third organic layer. Also, the second organic layer is desirable to satisfy equation (3) above. As a material forming such second organic layer, a pyrazine derivative which may be shown in following formula, can be given.

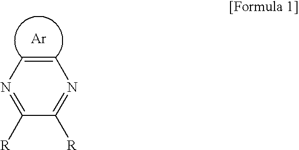

Where, Ar indicates aryl group, R indicates hydrogen, alkyl group with carbon number 1 to 10, alkyloxy group, dialkylamine group, or F, Cl, Br, I or CN.

Also, the material forming the second organic layer in the present invention is further desirable to be a hexaazatriphenylene derivative which may be shown in the formula below.

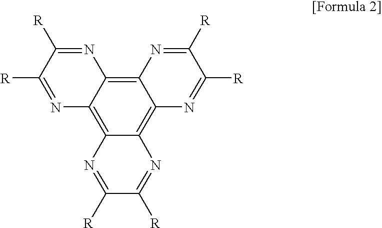

Where, R indicates hydrogen, alkyl group with carbon number 1 to 10, alkyloxy group, dialkylamine group, or F, Cl, Br, I or CN.

The organic electroluminescent display device according to the present invention is provided with an organic electroluminescent element having an element structure wedged between anode and cathode, and active matrix drive substrate with an active element to supply the organic electroluminescent element with display signal corresponding to each display pixel, and is a bottom emission type display device arranging the organic electroluminescent element on the active matrix drive substrate, and making the electrode provided on the substrate side among cathode and anode to a transparent electrode. And the organic electroluminescent element is provided with an anode, a cathode, a light emitting layer arranged between the anode and cathode, and at least three organic layers arranged between the light emitting layer and the anode, and is characterized by an absolute value |LUMO(A)| of energy level of a Lowest Unoccupied Molecular Orbital (LUMO) for the first organic layer provided to the anode side of organic layers and an absolute value |LUMO(B)| of energy level of a Lowest Unoccupied Molecular Orbital (LUMO) for the second organic layer provided adjacent to the cathode side of the first organic layer having a relationship of |LUMO(A)|<|LUMO(B)|, and an absolute value |HOMO(C)-LUMO(B)| for the difference between an energy level HOMO(C) of a Highest Occupied Molecular Orbital (HOMO) for the third organic layer provided adjacent to the cathode side of the second organic layer and LUMO(B) of the second organic layer having a relationship of |HOMO(C)-LUMO(B)|≦1.5 eV.

When an organic EL element for the organic electroluminescent display device according the present invention described above is a white light emitting element, it can be a display device after placing a color filter between the organic EL element and substrate.

And a picture signal drive circuit and a vertical scan signal drive circuit are provided to the active matrix drive substrate above, a picture signal applied through the picture signal drive circuit to the organic EL element, and a vertical scan signal applied through the vertical scan signal drive circuit to the organic EL element with pre-determined timing so that images to be displayed on each organic EL elements are generated.

The organic electroluminescent display device according to the other embodiment of the present invention is provided with an organic electroluminescent element having element structure wedged between anode and cathode, active matrix drive substrate with an active element to supply the organic electroluminescent element with display signal corresponding to each display pixel, and transparent sealing substrate provided facing to the active matrix drive substrate, and is a top emission type display device arranging the organic electroluminescent element between the active matrix drive substrate and the sealing substrate, and making the electrode provided on the sealing substrate side among cathode and anode to a transparent electrode. And the organic electroluminescent element is provided with an anode, a cathode, a light emitting layer arranged between the anode and cathode, and at least three organic layers arranged between the light emitting layer and the anode, and is characterized by an absolute value |LUMO(A)| of energy level of a Lowest Unoccupied Molecular Orbital (LUMO) for the first organic layer provided to the anode side of organic layers and an absolute value |LUMO(B)| of energy level of a Lowest Unoccupied Molecular Orbital (LUMO) for the second organic layer provided adjacent to the cathode side of the first organic layer having a relationship of |LUMO(A)|<|LUMO(B)|, and an absolute value |HOMO(C)-LUMO(B)| for the difference between an energy level HOMO(C) of a Highest Occupied Molecular Orbital (HOMO) for the third organic layer provided adjacent to the cathode side of the second organic layer and LUMO(B) of the second organic layer having a relationship of |HOMO(C)-LUMO(B)|≦1.5 eV.

When an organic EL element for the organic electroluminescent display device described above is a white light emitting element, it can be a color filter display device by placing a color filter device between the organic EL element and sealing substrate.

And a picture signal drive circuit and a vertical scan signal drive circuit are provided to the active matrix drive substrate above, a picture signal applied through the picture signal drive circuit to the organic EL element, and a vertical scan signal applied through the vertical scan signal drive circuit to the organic EL element with pre-determined timing so that images to be displayed on each organic EL elements are generated.

Because the organic EL display device in the present invention has the organic EL element in the present invention descried above, it shows high luminous efficiency which enables to decrease drive voltage, so that power consumption can be deceased.

According to the present invention, an organic EL element with high luminous efficiency which is able to decrease drive voltage can be obtained. Specially, when it is necessary to increase the thickness of a hole transport property material arranged between a light emitting layer and an anode to adjust cavity of an organic EL element, increase of drive voltage due to increased thickness can be suppressed even in such case.

Because the organic EL display device in the present invention is provided with the organic EL element described in the present invention above, it has high luminous efficiency and decreases drive voltage which enables to decrease power consumption.

### BRIEF DESCRIPTION OF THE DRAWINGS

FIG. 1 is a frame format illustrating energy levels of LUMO and HOMO for the first organic layer, second organic layer, and third organic layer in the present invention.

FIG. 2 is a frame format illustrating energy levels of LUMO and HOMO for the first organic layer, second organic layer and third organic layer in FIG. 1 when voltage applied.

FIG. 3 is a cross-section view illustrating a bottom emission type organic EL display device for the embodiment according to the present invention

FIG. 4 is a cross-section view illustrating a top emission type organic EL display device for the embodiment according to the present invention

FIG. 5 is a top view illustrating an organic EL element with a picture signal drive circuit and a vertical scan signal drive circuit connected.

### DETAILED DESCRIPTION OF INVENTION

The present invention will hereinafter be more specifically described in reference to embodiments; however, the present invention is not limited to the following embodiments.

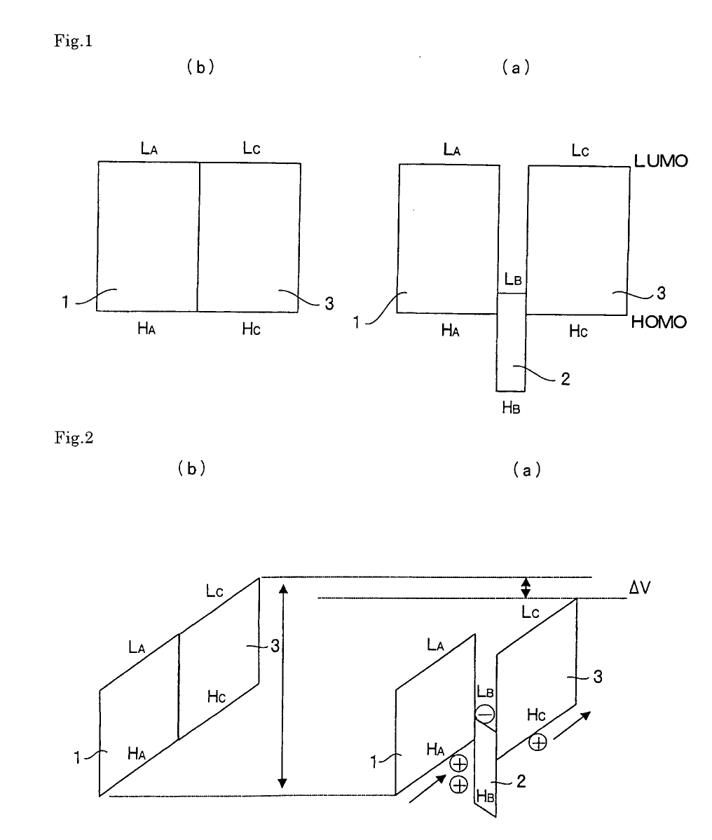

FIG. 1(a) is a drawing in frame format illustrating energy levels of HOMO and LUMO for the first organic layer 1, second organic layer 2, and third organic layer 3 of the present invention. For the first organic layer 1, LUMO is indicated as L_{A}, and HOMO as H_{A}. For second organic layer 2, LUMO is indicated as L_{B}, and HOMO as H_{B}. And for third organic layer 3, LUMO is indicated as L_{C}, and HOMO as H_{C}.

In the organic EL element according to the present invention as shown in FIG. 1(a), the absolute value of LUMO energy level L_{B} for the second organic layer 2 is larger than the energy level L_{A} of LUMO for the first organic layer 1. Also, the absolute value for the difference between the energy level H_{C} of HOMO for the third organic layer 3 and the energy level L_{C} of LUMO for the second organic layer 2 is 1.5 eV or below.

Also, the absolute value of H_{B} for the second organic layer 2 is larger than the absolute value of H_{A} for the first organic layer 1 in the example shown in FIG. 1(a).

FIG. 1(b) is a drawing illustrating energy level of the comparative example that does not arrange second organic layer 2 as an electron pull-out layer between the first organic layer 1 and the third organic layer 3. Since the first organic layer 1 and the third organic layer 3 are formed from same material in this example, L_{A} of the first organic layer 1 and L_{C} of the third organic layer 3 are in the same level, similarly H_{A} and H_{C} are the same level.

FIG. 2 is a frame format illustrating energy levels when voltage is applied to the laminate structures in (a) and (b) of the FIG. 1.

As shown in FIG. 2(a), because the difference between H_{C} of the third organic layer 3 and L_{B} of the second organic layer 2 is 1.5 eV or below in the organic EL element according to the present invention, the second organic layer 2 can easily pull electrons out of the third organic layer 3.

Also, since the absolute value of L_{B} for the second organic layer 2 is larger than the absolute value of L_{A} for the first organic layer 1, interfaces of the first organic layer 1 and second organic layer 2 become energy barriers and pulled out electrons are accumulated in the second organic layer 2 thereby a high electric field is applied locally.

Moreover, since the absolute value of H_{B} for the second organic layer 2 is larger than the absolute value of H_{A} for the first organic layer 1, interfaces of the first organic layer 1 and second organic layer 2 become energy barriers and holes are accumulated on the interfaces. In this way, high electrical field is also applied by the accumulated holes.

In the present invention, because high electrical field applied to the interfaces of the first organic layer 1 and second organic layer 2 when applying voltage to an organic EL element as above, which lead to changes in energy band and decreases in voltage by ΔV compared to the comparative example shown in FIG. 2(b), so that a decrease of drive voltage occurs.

### Embodiments 1-11 and Comparative Examples 1-3

The organic EL elements for embodiments 1-11 and comparative examples 1-3 having anode, hole injection unit, hole transport unit, orange light emitting layer, blue light emitting layer, electron transport layer and cathode shown in Table 1 below were fabricated. The numbers in ( ) in the Table 1 below indicate the thickness (nm) of each layer.

The anode was fabricated by forming a fluorocarbon (CFx) layer on a glass substrate with formed ITO (indium tin oxide) film. The fluorocarbon layer was formed by plasma polymerization of CHF3 gas. Thickness of the fluorocarbon layer is 1 nm.

A hole injection unit, hole transport unit, orange light emitting layer, blue light emitting layer, electron transport layer and cathode are formed by sequentially accumulating them on the anode fabricated as above. The hole injection unit and the hole transport unit are expediently distinguished in the Table 1 and 2, however, the hole injection unit and the hole transport unit are not specifically distinguished but to indicate function of hole injection and hole transport as a whole.

For embodiments 1-6 and comparative examples 1-3, the hole injection unit and the hole transport unit are formed by laminating NPB and HAT-CN6 in the order shown in Table 1.

HAT-CN6 is hexaazatriphenylenehexacarvonenityrl and has following structure.

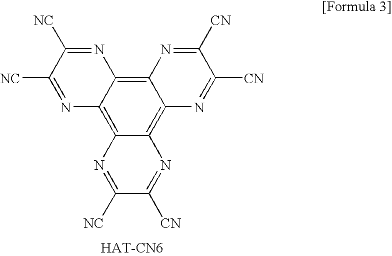

HAT-CN6 can be, for example, easily fabricated by one skilled in the art.

NPB is N,N′-di(naphthacene-1-yl)-N,N′-diphenylbenzdine and has following structure.

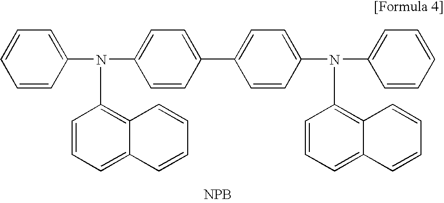

NPB is a third arylamine series material and is a hole transport property material. TPD, PhTPD, and PPD are used as third arylamine series materials in embodiments 7 to 10.

TPD is N,N′-bis(3-methylphenyl)-N,N′-diphenyl-benzidine and has following structure.

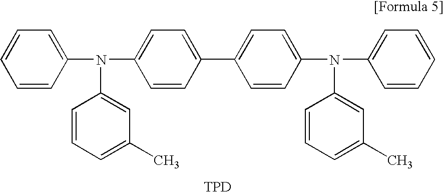

PhTPD is N,N,N′,N′-tetrakis(4-phenylphenyl)benzidine and has following structure.

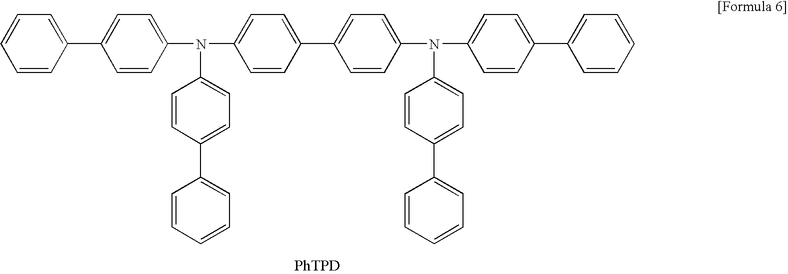

PPD is N,N′-bis(phenanthrene-9-yl)-N,N′-diphenyl-benzidine and has following structure.

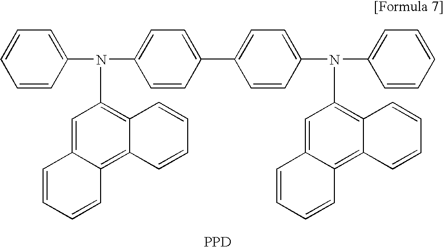

In embodiment 11, DTN is used as a material forming the second organic layer which is an electron pull-out layer. DTN is 2,3diphenyl-1,4,6,11-tetraaza-naphtacene and has following structure.

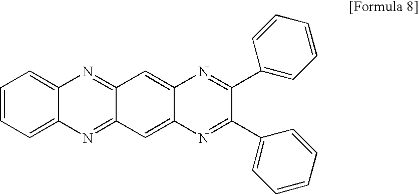

### 2,3-Diphenyt-1,4,6,11-Tetraaza-Naphtacene (DTN)

The first organic layer, second organic layer, and third organic layer in each embodiment are corresponding to the following laminate structure in hole injection unit and hole transport unit.

In embodiments 1-4, the laminate structure of NPB/HAT-CN6/NPB is corresponding to the laminate structures of the first organic layer/second organic layer/third organic layer.

In embodiment 5 and 6, NPB/HAT-CN6/NPB/HAT-CN6/NPB is corresponding to the laminate structures of the first organic layer/second organic layer/third organic layer (also is the first organic layer)/second organic layer/third organic layer. The NPB layer positioned in the center is the third organic layer for the laminated structure on the anode side and is the first organic layer for the laminated structure on the cathode side.

In embodiment 7, the laminate structure of TPD/HAT-CN6/NPD is corresponding to the laminate structures of the first organic layer/second organic layer/third organic layer.

In embodiment 8, the laminate structure of TPD/HAT-CN6/TPD is corresponding to the laminate structures of the first organic layer/second organic layer/third organic layer.

In embodiment 9, the laminate structure PhTPD/HAT-CN6/PhTPD is corresponding to the laminate structures of the first organic layer/second organic layer/third organic layer.

In embodiment 10, the laminate structure of PPD/HAT-CN6/PPD is corresponding to the laminate structures of the first organic layer/second organic layer/third organic layer.

In embodiment 11, the laminate structure of NPB/DTN/NPB is corresponding to the laminate structures of the first organic layer/second organic layer/third organic layer.

A white light emitting unit comprised of an orange light emitting layer and a blue light emitting layer formed on the hole transport unit formed as described above. The orange light emitting layer is arranged on the anode side and the blue light emitting layer is arranged on the cathode side. In addition, % in the table is weight %, unless otherwise specified.

For a orange light emitting layer, NPB is used as a hole transport property host material, TBADN is used as an electron transport property host material, and DBzR is used as a dopant material.

TBADN is 2-tertiary-butyl-9,10-di(2-naphthyl)anthracene and has following structure.

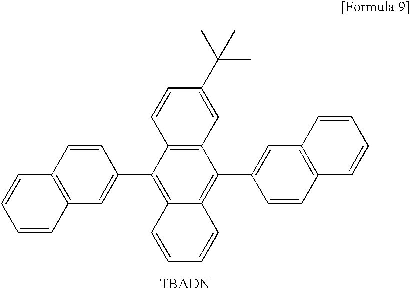

DBzR is 5,12-bis{4-(6-methylbenzothiazole-2-yl)phenyl}-6,11-diphenylnaphthacene) and has following structure.

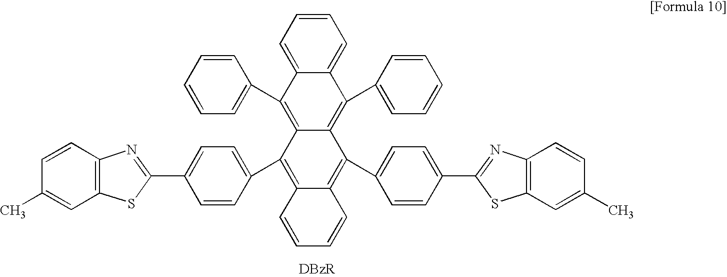

For a blue light emitting layer, TBADN is used as an electron transport property host material, NPB is used as a hole transport property material, and TBP is used as a dopant material.

TBP is 2,5,8,11-tetra-tertiary-butylperylene and has following structure.

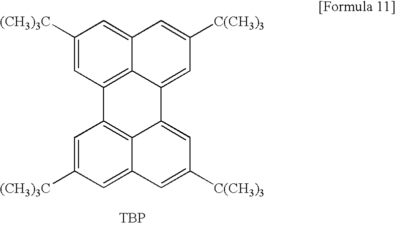

The electron transport layer consist of laminate structure of Alq layer and BCP layer is formed on the blue light emitting layer.

Alq is Tris-(8-quinolinolato)aluminum (III) and has following structure.

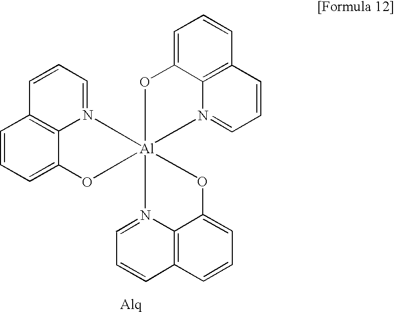

BCP is 2,9-dimethyl-4,7-diphenyl-1,10-phenanthroline and has following structure.

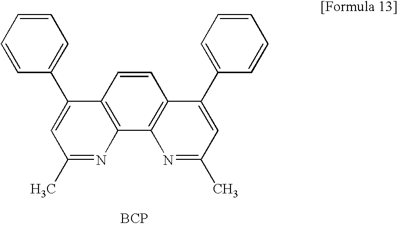

The cathode consisting of a laminated structure of a LiF layer and an Al layer is formed on the electron transport layer.

TABLE 1

| | | | | Orange | | | |
|---|---|---|---|---|---|---|---|
| | | | | Light | Blue | Electron | |
| | Anode | Hole Injection Unit | Hole Transport Unit | Emitting Layer | Light Emitting Layer | Transport unit | Cathode |
| Embodiment 1 | ITO/ | HAT-CN6/NPB/HAT-CN6 | NPB/HAT-CN6 | 70% NPB + 30% | 90% TBADN + 10% | Alq/BCP | LiF/Al |
| | CFx | (5)/(45)/(7.5) | (45)/(10) | TBADN + 3% | NPB + 2.5% TBP(50) | (3)/(7) | (1)/(200) |
| Embodiment 2 | | HAT-CN6/NPB/HAT-CN6 | NPB/HAT-CN6 | DBzR(60) | | | |
| | | (5)/(45)/(5) | (45)/(5) | | | | |
| Comparative | | HAT-CN6/NPB | | | | | |
| Example 1 | | (5)/(45) | | | | | |
| Embodiment 3 | ITO/ | HAT-CN6/NP8/HAT-CN6 | NPB/HAT-CN6 | 70% NPB + 30% | 90% TBADN + 10% | Alq/BCP | LiF/Al |
| | CFx | (10)/(45)/(15) | (45)/(20) | TBADN + 3% | NPB + 2.5% TBP(50) | (3)/(7) | (1)/(200) |
| Embodiment 4 | | HAT-CN6/NPB/HAT-CN6 | NP8/HAT-CN6 | DBzR(60) | | | |
| | | (10)/(45)/(10) | (4.5)/(10) | | | | |
| Comparative | | HAT-CN6/NPB | | | | | |
| Example 2 | | (10)/(45) | | | | | |
| Embodiment 5 | ITO/ | HAT-CN6/NPB/HAT- | NPB/HAT-CN6 | 70% NPB + 30% | 90% TBADN + 10% | Alq/BCP | LiF/Al |
| | CFx | CN6/NPB/HAT-CN6 | (30)/(10) | TBADN + 3% | NPB + 2.5% TBP(50) | (3)/(7) | (1)/(200) |
| | | (5)/(30)/(7)/(30)/(9) | | DBzR(60) | | | |
| Embodiment 6 | | HAT-CN6/NPB/HAT- | NPB/HAT-CN6 | | | | |
| | | CN6/NPB/HAT-CN6 | (30)/(5) | | | | |
| | | (5)/(30)/(5)/(30)/(5) | | | | | |
| Comparative | | HAT-CN6/NPB/NPB | | | | | |
| Example 3 | | (5)/(30)/(30) | | | | | |
| Embodiment 7 | ITO/ | HAT-CN6/TPD/HAT-CN6 | NPB/HAT-CN6 | 70% NPB + 30% | 90% TBADN + 10% | Alq/BCP | LiF/Al |
| | CFx | (5)/(45)/(5) | (45)/(5) | TBADN + 3% | NPB + 2.5% TBP(50) | (3)/(7) | (1)/(200) |
| Embodiment 8 | ITO/ | HAT-CN6/TPD/HAT-CN6 | TPD/HAT-CN6 | DBzR(60) | | | |
| | CFx | (5)/(45)/(5) | (45)/(5) | | | | |
| Embodiment 9 | ITO/ | HAT-CN6/PhTPD/HAT- | PhTPD/HAT- | | | | |
| | CFx | CN6 (5)/(45)/(5) | CN6 (45)/(5) | | | | |
| Embodiment 10 | ITO/ | HAT-CN6/PPD/HAT-CN6 | PPD/HAT-CN6 | | | | |
| | CFx | (5)/(45)/(5) | (45)/(5) | | | | |
| Embodiment 11 | ITO/ | HAT-CN6/NPB/DTN | NPB/HAT-CN6 | 70% NPB + 30% | 90% TBADN + 10% | Alq/BCP | LiF/Al |
| | CFx | (5)/(45)/(5) | (45)/(5) | TBADN + 3% | NPB + 2.5% TBP(50) | (3)/(7) | (1)/(200) |
| | | | | DBzR(60) | | | |

### Embodiment 12

The organic EL element of embodiment 12 having an anode, a hole injection unit, a hole transport unit, an orange light emitting layer, a blue light emitting layer, an intermediate unit, an orange light emitting layer, a blue light emitting layer, an electron transport layer and cathode shown in table 2 was fabricated.

TABLE 2

| | | | | Orange | Blue |
|---|---|---|---|---|---|
| | Anode | Hole Injection Unit | Hole Transport Unit | Light Emitting Layer | Light Emitting Layer |
| Embodiment 12 | ITO/CFx | HAT-CN6/NPB/HAT-CN6 | NPB/HAT-CN6 | 70% NPB + 30% TBADN + 3% | 90% TBADN + 10% NPB + 2.5% |
| | | (5)/(45)/(5) | (45)/(5) | DBzR(60) | TBP(50) |

| | | | Orange | Blue | Electron | |
|---|---|---|---|---|---|---|
| | Anode | Intermediate Unit | Light Emitting Layer | Light Emitting Layer | Transport unit | Cathode |
| Embodiment 12 | ITO/CFx | BCP/Li₂O/HAT-CN6 | 70% NPB + 30% | 90% TBADN + 10% NPB + 2.5% | BCP | LiF/Al |
| | | (10)/(0.2)/(50) | TBADN + 3% DBzR(60) | TBP(50) | (10) | (1)/(200) |

Except for making it in the laminated structure described in table 2, the organic EL element for embodiment 12 was fabricated in the same manner as each embodiment described above.

In the organic EL element described in Embodiment 12, two white light emitting unit (orange light emitting layer+blue light emitting layer) are laminated by using intermediate unit. The intermediate unit is formed by BCP/Li2O/HAT-CN6 laminated from anode side. In the intermediate unit, HAT-CN6 is an electron pull-out layer, Li2O is an electron injection layer and BCP is an electron transport layer. The electron pull-out layer within the intermediate unit pulls electron out of adjacent orange light emitting layer, supplies the electron to the blue light emitting unit on the anode side through the electron injection layer and the electron transport layer, and emits light by recombining with holes supplied from anode. Also, holes generated in the orange light emitting layer that had electron pulled out by the electron pull-out layer of the intermediate unit, and this hole recombine with electron supplied from cathode then emit light. In this way, by providing the intermediate unit between two light emitting units, respective recombination regions can be formed in each light emitting unit which enables to emit light efficiently.

The laminated structures of NPB/HAT-CN6/NPB in the hole injection unit and the hole transport unit for embodiment 12 correspond to the laminated structures of the first organic layer/second organic layer/third organic layer.

(Evaluation of Organic EL Elements)

Drive voltage and luminous efficiency were measured for each organic EL element fabricated as above. The measurement results are shown in Table 3. In addition, the measurement results are the value at drive current of 20 mA/cm².

TABLE 3

| | Drive Voltage | Luminous Efficiency |
|---|---|---|
| | (V) | (cd/A) |
| Embodiment 1 | 4.6 | 17.9 |
| Embodiment 2 | 4.5 | 21.3 |
| Comparative Example 1 | 4.9 | 15.9 |
| Embodiment 3 | 4.7 | 19.6 |
| Embodiment 4 | 4.7 | 20.4 |
| Comparative Example 2 | 5.1 | 15.7 |
| Embodiment 5 | 4.2 | 17.7 |
| Embodiment 6 | 4.2 | 16.0 |
| Comparative Example 3 | 5.0 | 15.6 |
| Embodiment 7 | 4.5 | 22.0 |
| Embodiment 8 | 4.4 | 23.0 |
| Embodiment 9 | 4.6 | 21.2 |
| Embodiment 10 | 4.6 | 21.0 |
| Embodiment 11 | 4.9 | 16.1 |
| Embodiment 12 | 9.0 | 40.5 |

As it is apparent from the comparison of embodiment 1-6 and comparative example 1-3 corresponding to each embodiment, the drive voltage can be decreased and the luminous efficiency can be improved by providing a structure of first organic layer/second organic layer/third organic layer between anode and light emitting layer according to the present invention.

Also as it is apparent from the embodiment 7-10, the same effect is shown when the third arylamine series material other than NPB is used as a hole transport property material.

Also as it is apparent from the embodiment 11, the same effect is shown when DTN is used instead of HAT-CN6 as a material forming the second organic layer (electron pull-out layer).

Embodiment 12 is the organic EL element having a structure with two light emitting units laminated on contact with the intermediate unit as described above, and drive voltage is about double because two light emitting units are laminated, however, it can be found that the luminous efficiency improved to double.

Also, drive voltage can be further decreased when multiple second organic layers are intervened, such as first organic layer/second organic layer/third organic layer (also it is first organic layer)/second organic layer/third organic layer as shown in embodiment 5 and 6. Also, as it is apparent from comparison of embodiment 5 and 6, the luminous efficiency can be further improved by gradually thickening the film thickness of the second organic layer as it gets closer towards the cathode when multiple second organic layers are intervened.

As it is apparent from above results, the organic EL element according to the present invention can increase the luminous efficiency and decrease drive voltage by providing the first organic layer/second organic layer/third organic layer between the anode and the light emitting layer.

Therefore, the drive voltage can be decreased even when increasing the distance between anode and light emitting layer for adjusting cavity and so on.

[Organic EL Display Device]

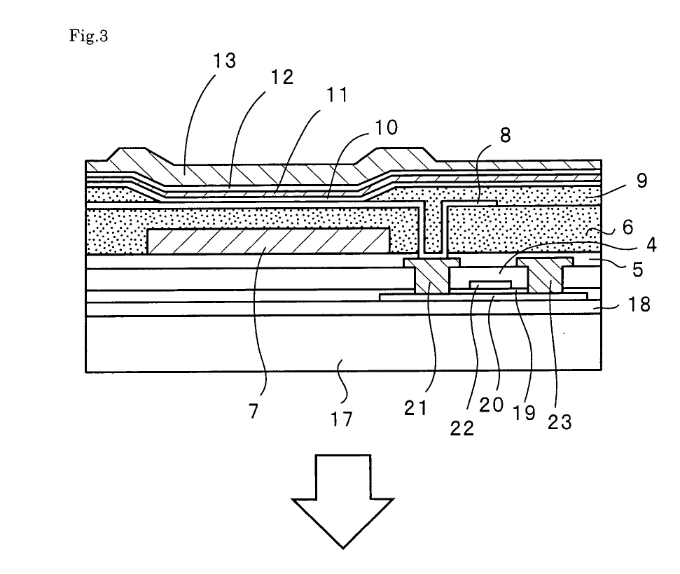

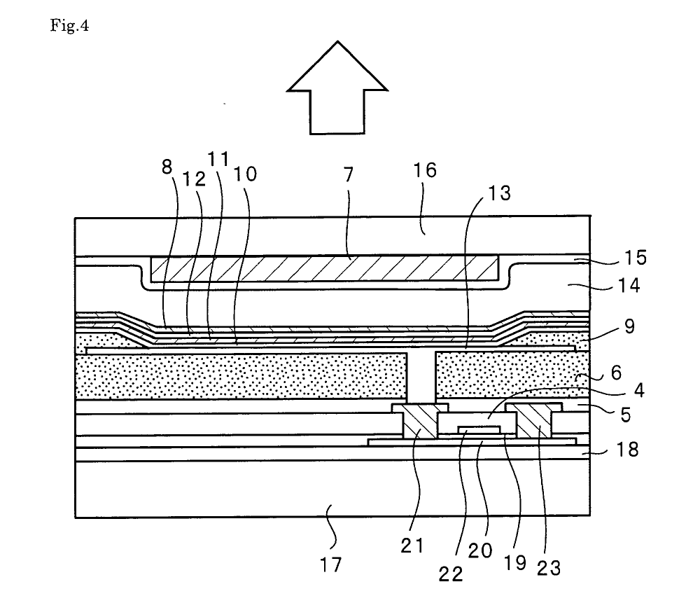

FIG. 3 is a cross-section diagram illustrating a bottom emission type organic EL display device according to the present invention. TFT is used as an active element to drive emission for each pixel in this organic EL display device. In addition, diode may also be used as an active element. Also, a color filter is provided to this organic EL display device. This organic EL display device is a bottom emission type display device that displays by emitting light to lower side of substrate 17 as indicated with arrow.

Refer to the FIG. 3, the first insulating layer 18 is provided on the substrate 17 comprised of transparent substrate such as glass. The first insulating layer 18 is formed from, for example, SiO2 and SiNX. Channel region 20 comprised of polysilicon layer is formed on the first insulating layer 18. Drain electrode 21 and source electrode 23 are formed on the channel region 20, and gate electrode 22 is provided through the second insulating layer 19 between the drain electrode 21 and source electrode 23. Fourth insulating layer 4 is provided on the gate electrode 22. The second insulating layer 19 is formed from, for example, SiNX and SiO2, and third insulating layer 4 is formed from SiO2 and SiNx.

Fourth insulating layer 5 is formed on the third insulating layer 4. The forth insulating layer 5 is formed, for example, from SiNX. Color filter layer 7 is provided to the portion of pixel region on the fourth insulating layer 5. R (red), G (Green) or B (blue) color filters are provided for the color filter layer 7. Planarizing film 6 is provided on the color filter layer 7. The through hole portion is formed on the first planarizing film 6 above drain electrode 21, and hole injection electrode (anode) 8 comprised of ITO (indium tin oxide), which formed on the first planarizing film 6, is adopted in the through hole portion. Hole injection/transport unit 10 is formed on the hole injection electrode (anode) 8 in the pixel region. Second planarizing film 9 is formed on the portion other than the pixel region.

The hole injection/transport unit 10 has laminated structure with the first organic layer/second organic layer/third organic layer according to the present invention.

A light emitting layer 11 is provided on the hole injection/transport unit 10. An electron transport layer 12 is provided on the light emitting layer 11, and an electron injection electrode (cathode) 13 is provided on the electron transport layer 12.

As above, in the organic EL element in the embodiment, the organic EL element is comprised by laminating the hole injection electrode (anode) 8, the hole injection/transport unit 10, the light emitting layer 11, the electron transport layer 12, and the electron injection electrode (cathode) 13 on the pixel region.

Since the light emitting unit laminating the orange light emitting layer and blue light emitting layer is used in the light emitting layer 11 of the embodiment, white light is emitted from the light emitting layer 11. This white light emission is outputted to outside through substrate 1, however, color of R, G or B outputted according to the color of the color filter layer 7 since the color filter layer 7 is provided on the emission side. If the element emit light in monochrome, no color filter layer 7 is required.

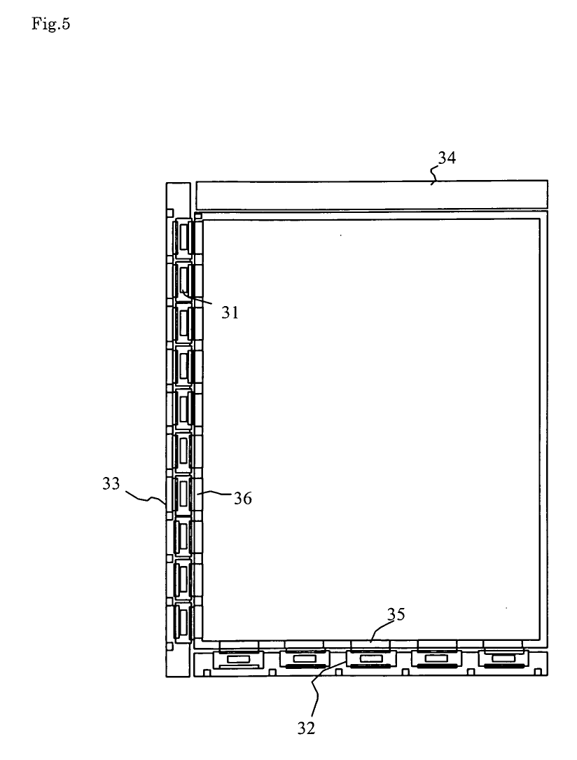

FIG. 4 is a cross section view illustrating a top emission type organic EL display device of the embodiment according to the present invention. The organic EL display device in the embodiment is the top emission type organic EL display device which displays by outputting light above the substrate 17 as illustrated by an arrow

Portion from the substrate 17 to the cathode 8 is fabricated almost the same as the embodiment shown in FIG. 3. However, the color filter layer 7 is arranged above the organic EL element, not on the fourth insulating layer 5. Specifically, mount color filter layer 7 on the transparent sealing substrate 16 comprised of material like glass, coat an overcoat layer 15 over it, then adhering on anode 8 through transparent adhesive layer 14. Also in this embodiment, the positions of anode and cathode are opposite from those of the embodiment shown in FIG. 3.

A transparent electrode is formed as an electrode 8, and it is formed, for example, by laminating an ITO with a thickness of approximately 100 nm and silver with a thickness of approximately 20 nm. A reflecting electrode is formed as a cathode 13 and for example, thin film of aluminum, chromium, or silver with approximately 100 nm is formed. An overcoat layer 15 is formed in approximately 1 μm by acrylic resin and on. A color filter layer 7 can be a pigment type or a dye type. Its thickness is approximately 1 μm.

The white light emitted from the light emitting layer 11 is outputted to outside through the sealing substrate 16, however, color of R, G, or B depending on the color of the color filter layer 7 is outputted because the color filter layer 7 is provided on the light emitting side. Since the organic EL display device in the embodiment is a top emission type, the region provided with a thin film transistor can also be used as a pixel region, and color filter 7 is provided to the larger region than the embodiment shown in FIG. 3. According to the embodiment, wider region can be used as a pixel region so that aperture ratio will increase. Also, the light emitting layer with multiple light emitting units can be formed without considering an effect of the active matrix, so that design freedom will increase.

The glass plate is used as a sealing substrate in the embodiment above, however, sealing substrate is not limited to grass glass plate, and membranous material, for example, oxide film such as SiO2, or nitride film such as SiNx, can also be used as a sealing substrate. In such case, the membranous sealing substrate can be formed directly on an element so that no transparent adhesive layer is needed.

FIG. 5 is a top view showing the picture signal drive circuit and the vertical scan signal drive circuit connected to the organic EL element described above.

More specifically, the drive IC chip 31 is comprised of a picture signal drive IC chip which drives the organic EL panel and a vertical scan signal drive IC chip. Five of IC chip 31 mounted on the drive circuit board 32 on the bottom of FIG. 5 is the drive IC on the vertical scan signal side, and ten of IC chip 31 is the drive IC chip on the picture signal side. The drive circuit board 32 and 33 are the tape carrier package which has Drive IC chip 31 mounted by tape automated bonding (TAB) method and it is divided into two, for picture signal drive circuit and for scan signal drive circuit, as shown in FIG. 5.

And each IC chip 31 mounted on these drive circuit board 32 and 33 applies picture signal and vertical scan signal on above organic EL element with predetermined timing so that images to be displayed on each organic EL element are generated. Power circuit board 34 supplies drive voltage.

In addition, the terminal group is that the scan circuit connection terminal 35 and the image signal circuit connection terminal 36 gathered with their respective lead-out wiring portions into plurality of a unit of tape carrier package TCP loaded with the integrated circuit chip 31. The lead-out wiring leading from the matrix portion of each group to the external connection terminal portion is beveled as they get closer to the both ends. This is to align array pitch of the package TCP and connection terminal pitch for each drive circuit board 32 and 33 to the organic EL panel terminals 35 and 36.

This EL panel is assembled by sealing overlapped substrates 16 and 17, and cutting off top and bottom substrates. And in the production of the organic EL panel in the present invention, for small sizes, to improve the throughput, simultaneously process multiple pieces of device with one piece of glass substrate then divide into pieces, and for large size, to share production facility, process standardized sized glass regardless of products and decrease the sizes according to the product, in both cases, the glass is cut down after going through a series of processes.

Based on above, according to the present invention, the organic electroluminescent element having high luminous efficiency and able to decrease drive voltage, and the organic electroluminescent display device using the same can be obtained.

In addition, the present invention is not limited to the above embodiments, but may be variously altered in terms of a constitution of the invention, and in claim construction, claims should be most widely construed.

What is claimed is:

1. An organic electroluminescent element comprising an anode, a cathode, a light emitting layer arranged between said anode and cathode, and at least three organic layers arranged between said light emitting layer and said anode; wherein an absolute value |LUMO(A)| of an energy level of a Lowest Unoccupied Molecular Orbital (LUMO) for a first organic layer adjacent to an anode side of said organic layers and an absolute value |LUMO(B)| of an energy level of the LUMO for a second organic layer adjacent to a cathode side of the first organic layer are in a relationship of |LUMO(A)|<|LUMO(B)|, wherein an absolute value |HOMO(C)-LUMO(B)| for a difference between an energy level HOMO(C) of a Highest Occupied Molecular Orbital (HOMO) for a third organic layer adjacent to said cathode side of said second organic layer and LUMO(B) of said second organic layer is in a relationship of |HOMO(C)-LUMO(B)|≦1.5 eV.

2. The organic electroluminescent element according to claim 1, wherein at least one of said first organic layer or said third organic layer is formed from a third arylamine series material.

3. The organic electroluminescent element according to claim 1, wherein said second organic layer is formed from a pyrazine derivative shown in a structural formula below: 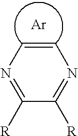
where, Ar indicates an aryl group, and R is selected from a group consisting of a hydrogen, an alkyl group with carbon number 1 to 10, an alkyloxy group, a dialkylamine group, or F, Cl, Br, I or CN.

4. The organic electroluminescent element according to claim 1, wherein said second organic layer is formed from a hexaazatriphenylene derivative shown in a structural formula below: 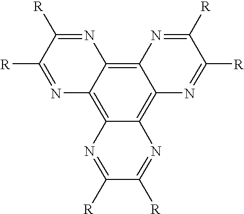
where, R is selected from a group consisting of a hydrogen, an alkyl group with carbon number 1 to 10, an alkyloxy group, a dialkylamine group, or F, Cl, Br, I or CN.

5. The organic electroluminescent element according to claim 1, wherein an absolute value |HOMO(A)| of an energy level of a Highest Occupied Molecular Orbital (HOMO) for the first organic layer and an absolute value |HOMO(B)| of an energy level of HOMO for the second organic layer are in a relationship of |HOMO(A)|<|HOMO(B)|.

6. The organic electroluminescent element according to claim 5, wherein at least one of said first organic layer or said third layer is formed from a third arylamine series material.

7. The organic electroluminescent element according to claim 5, wherein said second organic layer is formed from a pyrazine derivative shown in a structural formula below: 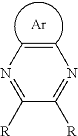
where, Ar indicates an aryl group, and R is selected from a group consisting of a hydrogen, an alkyl group with carbon number 1 to 10, an alkyloxy group, a dialkylamine group, or F, Cl, Br, I or CN.

8. The organic electroluminescent element according to claim 5, wherein said second organic layer is formed from a hexaazatriphenylene derivative shown in a structural formula below: 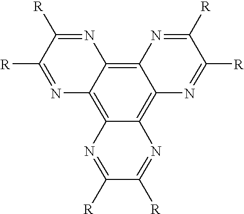
where, R is selected from a group consisting of a hydrogen, an alkyl group with carbon number 1 to 10, an alkyloxy group, a dialkylamine group, or F, Cl, Br, I or CN.

9. An organic electroluminescent display device comprising:
an organic electroluminescent element having an element structure located between an anode and a cathode;
an active matrix drive substrate having an active element to supply a display signal to a plurality of display pixels;
wherein said organic electroluminescent display device is a bottom emission type organic luminescent display device comprising said organic electroluminescent element arranged on said active matrix drive substrate, and a transparent electrode provided on a substrate side among said anode and cathode, wherein, said organic electroluminescent element comprising said anode, said cathode, a light emitting layer arranged between said anode and cathode, and at least three organic layers arranged between said light emitting layer, wherein an absolute value |LUMO(A)| of an energy level of a Lowest Unoccupied Molecular Orbital (LUMO) for a first organic layer adjacent to an anode side of said organic layers and an absolute value |LUMO(B)| of an energy level of the LUMO for a second organic layer adjacent to a cathode side of said first organic layer are in a relationship of |LUMO(A)|<|LUMO(B)|, wherein an absolute value |HOMO(C)-LUMO(B)| for the difference between an energy level HOMO(C) of a Highest Occupied Molecular Orbital (HOMO) for a third organic layer provided adjacent to a cathode side of said second organic layer and LUMO(B) of said second organic layer is in a relationship of |HOMO(C)-LUMO(B)|≦1.5 eV.

10. The organic electroluminescent display device according to claim 9, wherein said organic electroluminescent element is a white light emitting element, wherein a color filter is arranged between said organic electroluminescent element and said substrate.

11. The organic electroluminescent display device according to claim 9, wherein said active matrix drive substrate further comprise a picture signal drive circuit, and a vertical scan signal drive circuit;
where a picture signal is applied to said organic EL element through said picture signal drive circuit;
where a vertical scan signal is applied to said organic EL element with a predetermined timing through said vertical scan signal drive circuit; and
thereby an image to be displayed on each organic EL element is generated.

12. An organic electroluminescent display device comprising:
an organic electroluminescent element having an element structure located between an anode and a cathode;
an active matrix drive substrate having an active element to supply a display signal to a plurality of display pixels; and
a transparent sealing substrate facing attached to said active matrix drive substrate;
wherein said organic electroluminescent display device is a top emission type organic luminescent display device comprising said organic electroluminescent element arranged between said active matrix drive substrate and said transparent sealing substrate, and a transparent electrode provided on said transparent sealing substrate, wherein, said organic luminescent element comprising said anode, said cathode, a light emitting layer arranged between said anode and cathode, and at least three organic layers arranged between said light emitting layer, wherein an absolute value |LUMO(A)| of an energy level of a Lowest Unoccupied Molecular Orbital (LUMO) for a first organic layer provided to an anode side of said organic layers and an absolute value |LUMO(B)| of an energy level of the second organic layer adjacent to a cathode side of a first organic layer are in a relationship of |LUMO(A)|<|LUMO(B)|, wherein an absolute value |HOMO(C)-LUMO(B)| for a difference between an energy level HOMO(C) of a Highest Occupied Molecular Orbital (HOMO) for a third organic layer adjacent to a cathode side of said second organic layer and LUMO(B) of said second organic layer is in a relationship of |HOMO(C)-LUMO(B)|≦1.5 eV.

13. The organic electroluminescent display device according to claim 12, wherein said organic electroluminescent element is a white light emitting element, wherein a color filter is arranged between said organic electroluminescent element and said sealing substrate.

14. The organic electroluminescent display device according to claim 12 wherein said active matrix drive substrate further comprise a picture signal drive circuit and a vertical scan signal drive circuit;
where a picture signal is applied to said organic EL element through said picture signal drive circuit;
where a vertical scan signal is applied to said organic EL element with a predetermined timing through said vertical scan signal drive circuit; and
thereby an image to be displayed on each organic EL element is generated.
